(19) United States
(12) Patent Application Publication
(10) Pub. No.: US 2025/0357156 A1
(43) Pub. Date: Nov. 20, 2025

(54) METHOD FOR REUSING A SUPPORTING WAFER AND METHOD FOR MANUFACTURING CHIPS

(71) Applicant: DISCO CORPORATION, Tokyo (JP)

(72) Inventors: Tasuku KOYANAGI, Tokyo (JP); Yuki KONISHI, Tokyo (JP)

(73) Assignee: DISCO CORPORATION, Tokyo (JP)

(21) Appl. No.: 19/201,175

(22) Filed: May 7, 2025

(30) Foreign Application Priority Data
May 17, 2024 (JP) 2024-081141

(51) Int. Cl. H01L 21/67; B23K 26/40; B23K 101/40; H01L 21/78

(52) U.S. Cl. CPC H01L 21/67092; B23K 26/40; H01L 21/78; B23K 2101/40

(57) ABSTRACT

A method for reusing a supporting wafer, which has chips or a wafer bonded thereon with an adhesive agent, by separating the supporting wafer from the chips or the wafer and thereafter removing the adhesive agent from the supporting wafer, is provided. The method includes an adhesive agent removing process including irradiating the adhesive agent remaining on the supporting wafer after separating the supporting wafer from the chips or the wafer with a laser beam to remove the adhesive agent.

### CROSS REFERENCE TO RELATED APPLICATION

This application is based upon and claims the benefit of priority from the prior Japanese Patent Application No. 2024-081141 filed on May 17, 2024; the entire contents of which are incorporated herein by reference.

### FIELD

The present disclosure relates to a method for reusing a supporting wafer and a method for manufacturing chips.

### BACKGROUND

As disclosed in, for example, Japanese Patent Application Laid-Open Publications No. 2012-134231 and No. 2015-233049, a method to manufacture laminated devices is known. According to the publications, a provisional wafer may be produced by bonding qualified semiconductor device chips onto a supporting wafer, the provisional wafer with the semiconductor device chips adhering thereon may be bonded to a semiconductor wafer to form a bonded wafer, and thereafter, the supporting wafer composing the provisional wafer may be separated from the bonded wafer to manufacture laminated devices. As the bonded wafer is formed, the semiconductor devices on the provisional wafer and the semiconductor devices on the semiconductor wafer are stacked in a direction of thickness of the wafers.

On the supporting wafer separated from the bonded wafer, an adhesive agent used to attach the semiconductor device chips thereon may remain. In order to reuse the supporting wafer to produce more bonded wafers, it is preferable the adhesive agent remaining on the supporting wafer be removed. The adhesive agent remaining on the supporting wafer may be removed with, for example, as disclosed in Japanese Patent Application Laid-Open Publication No. H09-069509, an organic solvent.

### SUMMARY

However, using the organic solvent may increase a cost for processing the used liquid. The present disclosure is made in view of such a problem and is aimed at providing a technique that enables a supporting wafer to be reused while reducing a processing cost.

A method for reusing a supporting wafer, which has chips or a wafer bonded thereon with an adhesive agent, by separating the supporting wafer from the chips or the wafer and thereafter removing the adhesive agent from the supporting wafer, is provided. The method includes an adhesive agent removing process including irradiating the adhesive agent remaining on the supporting wafer after separating the supporting wafer from the chips or the wafer with a laser beam to remove the adhesive agent.

According to another aspect of the present disclosure, a method for manufacturing a plurality of chips, which are divided from a wafer on which a plurality of devices are formed respectively in a plurality of regions defined by a plurality of streets, is provided. The method includes a bonding process including bonding the supporting wafer, which is reused by application of the method for reusing the supporting wafer, to the wafer with the adhesive agent, and a chip forming process including dividing the wafer along the streets to be divided into individual chips after the bonding process.

According to the present invention, a technique to reduce processing costs, enabling the support wafer to be reused, is provided.

### BRIEF DESCRIPTION OF THE DRAWINGS

FIG. 1 is a schematic perspective view of a first semiconductor wafer and of a second semiconductor wafer.

FIG. 2 is an illustrative view of a bonding process, showing an arrangement at a beginning of the bonding process.

FIG. 3 is an illustrative of the bonding process, showing an arrangement at an ending of the bonding process.

FIG. 4 is an illustrative view of a supporting board separating process.

FIG. 5 is an illustrative view of an adhesive agent removing process.

FIG. 6 is another illustrative view of the adhesive agent removing process.

### DESCRIPTION OF EMBODIMENTS

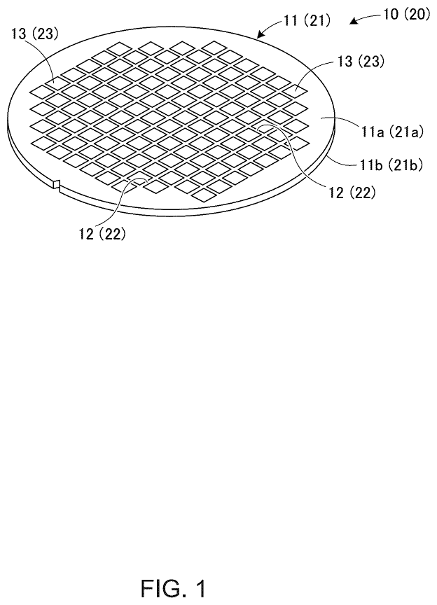

An embodiment of the present disclosure will be described below with reference to the accompanying drawings. First, referring to FIG. 1, a first semiconductor wafer and a second semiconductor wafer to be used in manufacturing laminated devices will be described. FIG. 1 is a schematic perspective view of a first semiconductor wafer and of a second semiconductor wafer.

As shown in FIG. 1, a first semiconductor wafer 10 includes a disk-shaped first base 11 having a front surface 11a and a back surface 11b. On the front surface 11a of the first base 11, a plurality of first divide-preset lines (streets) 12, which intersect with one another in a grid formation, are set. The first semiconductor wafer 10 further includes a plurality of first semiconductor devices 13, which are each composed of, for example, LSI (Large-Scale Integration) and arranged respectively in regions that are defined (sectioned) by the first divide-preset lines 12.

A second semiconductor wafer 20 is similar to the first semiconductor wafer 10 in appearance but differs in a size of the devices arranged thereon, the material, and internal structure thereof. Therefore, in the following description, items in the second semiconductor wafer 20 similar to those in the first semiconductor wafer 10 will be referred to by the same names, except for an ordinal term “first” being replaced with “second,” and, in FIG. 1, reference numerals of those, in which a tens digit “1” is replaced with “2,” are indicated in parentheses alongside the reference numerals of those in the first semiconductor wafer 10.

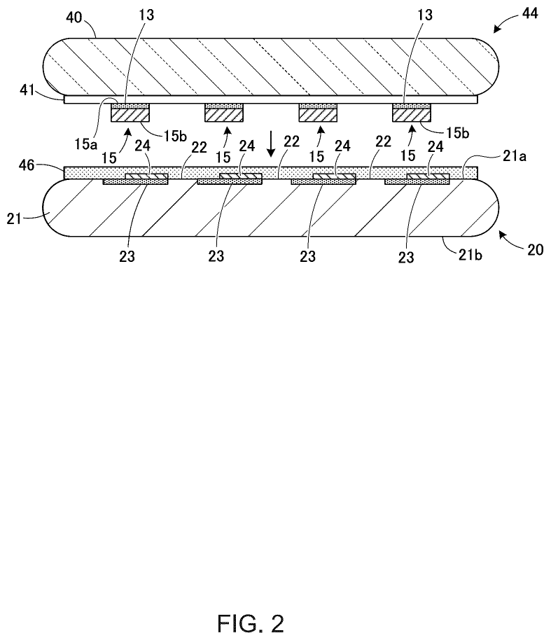

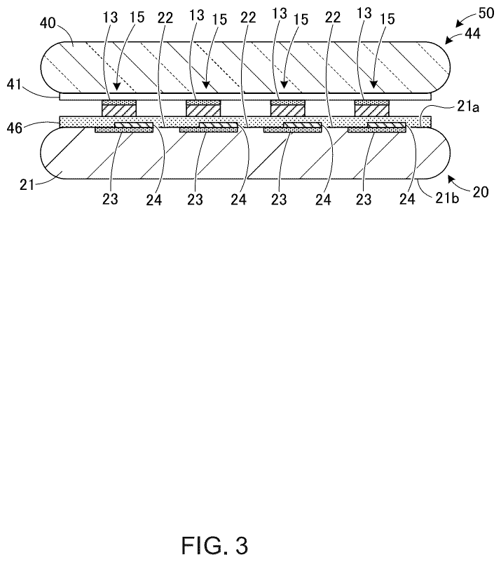

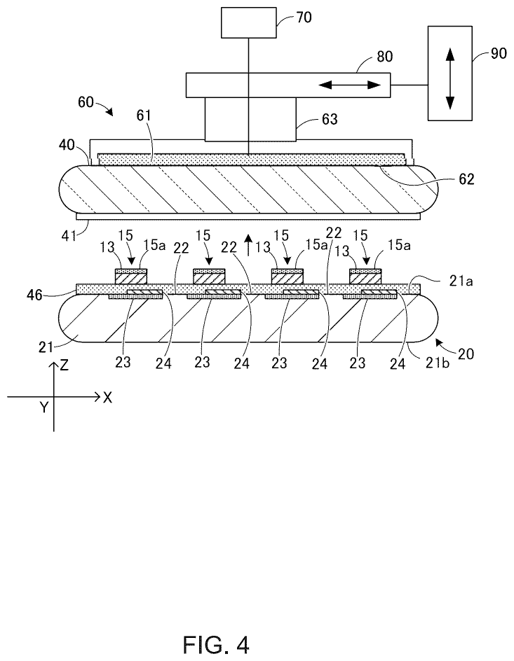

Next, a manufacturing method for laminated devices (chips) according to the present embodiment will be described with reference to FIGS. 2-4. FIGS. 2 and 3 are illustrative views of a bonding process, showing arrangements at the beginning and at the ending, respectively. FIG. 4 is an illustrative view of a supporting board separating process.

First, the first semiconductor wafer 10 is cut along the first divide-preset lines 12 (cutting process). The cutting process is performed with, for example, a dicer (dicing cutter). Thereby, the first semiconductor wafer 10 is diced into a plurality of first device chips 15, each containing a first semiconductor device 13. The first semiconductor devices 13 are provided on a front surface 15a side of the first device chips 15.

Once the first device chips 15 are formed, a provisional wafer 44 is thereafter produced (provisional wafer producing process). In the provisional wafer producing process, first, a supporting board 40, which may be made of, for example, sapphire, quartz glass, silicon, or SiC (silicon carbide), is prepared. The supporting board 40 is an example of the supporting wafer composing the provisional wafer. The supporting wafer (the supporting board 40) may be a support wafer that has undergone the reuse method described below. Next, an adhesive agent 41 is applied to the supporting board 40. The adhesive agent 41 is for bonding the supporting board 40 to the first device chips 15 provisionally, but a type or a curing mechanism thereof is not necessarily limited as long as the supporting board 40 is separable in a later process. The adhesive agent 41 may be of, for example, a polymer resin such as acrylic resin, epoxy resin, or silicone resin or may be an agent with any curable property that may cure with UV, heat, or volatilization. Thereafter, the front surfaces 15a of the first device chips 15, on which the first semiconductor devices 13 are formed, are pressed against the adhesive agent 41 on the supporting board 40 to bond the first device chips 15 to the supporting board 40. As such, the provisional wafer 44 as shown in FIG. 2 is produced.

Optionally, along the first divide-preset lines 12 on the front surface 11a of the first semiconductor wafer 10, cutting grooves that do not divide the first semiconductor wafer 10 apart may be formed with a cutting blade, and after bonding the first semiconductor wafer 10 having the cutting grooves formed thereon to the supporting board 40, a back surface 15b of the first semiconductor wafer 10 may be ground and thinned. As such, by thinning the first semiconductor wafer 10 and causing the cutting groove to emerge, the first device chips 15 may be formed, and the provisional wafer 44 may be produced.

In the provisional wafer producing process, as shown in FIG. 2, the plurality of first device chips 15 are bonded to the supporting board 40 in an arrangement such that the positions of the first device chips 15 on the supporting board 40 correspond to the positions of the second semiconductor devices 23 on the second semiconductor wafer 20 respectively. Electrodes 24 shown in FIG. 2 are formed in the second semiconductor devices 23 and will be connected with electrodes (not shown) in the first semiconductor devices 13 in a later process.

Once the provisional wafer 44 is produced, the provisional wafer 44 is bonded with the second semiconductor wafer 20 to produce a bonded wafer 50 as shown in FIG. 3 (bonded wafer producing process). In the bonded wafer producing process, first, an adhesive agent 46 is applied to a front surface 21a of the second semiconductor wafer 20, on which the second semiconductor devices 23 are formed. The adhesive agent 46 is a different agent from the adhesive agent 41 and has an adhesive property that ensure a bonded state in subsequent processes and further when the laminated devices are used as marketed products. Next, in a vacuum environment, the back surfaces 15b of the first device chips 15 on the provisional wafer 44 are located to face the front surface 21a of the second semiconductor wafer 20 (the adhesive agent 46 side). Thereafter, the provisional wafer 44 and the second semiconductor wafer 20 are aligned with each other so that each first device chip 15 and each second semiconductor device 23 are located to correspond to each other and align in the vertical direction. Finally, the provisional wafer 44 and the second semiconductor wafer 20 are bonded and laminated with the adhesive agent 46 to form the bonded wafer 50 as shown in FIG. 3.

After the bonded wafer 50 is formed, the supporting board 40 is removed from the bonded wafer 50, as shown in FIG. 4 (supporting board removing process). In the supporting board removing process, the adhesive agent 41 is processed through a predetermined treatment to lose or reduce the adhesive strength thereof, and thereafter, the supporting board 40 is removed from the bonded wafer 50. The predetermined treatment is not particularly limited but may include, for example, irradiation with UV light. For example, first, the adhesive agent 41 may be irradiated with UV light emitted from a UV emitting unit, which is not shown, to lose or reduce the adhesive strength thereof. Next, while the second semiconductor wafer 20 composing the bonded wafer 50 is held by a holding device which is not shown, the supporting board 40 composing the bonded wafer 50 may be suctioned and held against a holder table 60, and a lift/lower assembly 90 may uplift the supporting board 40. Accordingly, the bonded wafer 50 may be divided at the adhesive agent 41, of which adhesive strength is lost or reduced, and as shown in FIG. 4, the supporting board 40 is removed from the bonded wafer 50.

In the above example, the UV light is emitted to remove the supporting board 40; however, alternatively, a laser beam may be emitted to burn off the adhesive agent 41 for removing the supporting board 40.

The holder table 60 as shown in FIG. 4 is a suctioning chuck table, in which a suction source 70 is operated to generate a negative pressure at a holder surface 62 being a surface of a porous sheet 61. The holder table 60 includes a spindle 63, a horizontal movable assembly 80, and a lift/lower assembly 90, which may move the holder table 60 to rotate on a Z-axis direction, move in a horizontal direction (e.g., X-axis direction or Y-axis direction), and move in a vertical direction (Z-axis direction), respectively.

After the supporting board 40 is removed, the first device chips 15 that are now exposed are coated with a resin (resin coating process). In the resin coating process, gaps between the first device chips 15 and the front surfaces 15a of the first device chips 15 are covered with a resin such as epoxy resin. Thereafter, a top surface of the resin is ground with a grinding device. Thereby, with the first device chips 15 being entirely covered, the top surface of the resin is flattened.

Once the first device chips 15 are coated with the resin, the electrodes of the first device chips 15 and the electrodes 24 of the second semiconductor devices 23 are connected respectively (electrodes connecting process). In the electrodes connecting process, for example, through-holes, formed through the resin from the top surface of the resin to the electrodes of the first device chips 15, and through-holes, formed through the resin from the top surface of the resin to the electrodes 24 of the second semiconductor devices 23, may be formed. Thereafter, copper may be poured into the through-holes from the top surface of the resin so that portions of the copper overflowing from the through-holes may contact one another on the top surface of the resin. As such, through-electrodes that electrically connect the first device chips 15 with the second semiconductor devices 23 may be formed.

Once the through-electrodes are formed, the back surface 21b of the second semiconductor wafer 20 is ground and polished, and the second semiconductor wafer 20 is divided into individual laminated devices (dividing process, chip forming process). The dividing process may be performed with, for example, a dicer. In the dividing process, the second semiconductor wafer 20 is cut along the second divide-preset lines 22 to be divided into individual laminated devices (chips), and thereby the plurality of laminated devices are manufactured. Each of the laminated devices includes the first device chip 15 and the second semiconductor device 23 that are electrically connected through the through-electrodes.

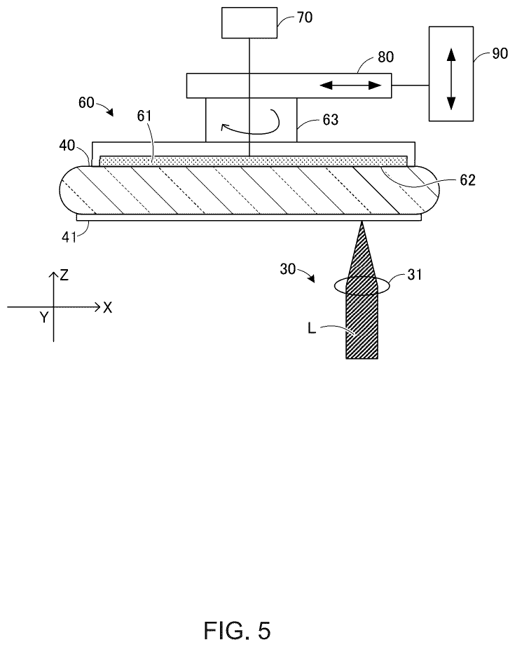

A method for reusing the supporting wafer according to the present embodiment will be described with reference to FIG. 5. FIG. 5 is an illustrative view of an adhesive agent removing process. As described above, in the manufacturing method for laminated devices, the supporting board 40 being the supporting wafer is separated from the bonded wafer 50. More specifically, the supporting board 40 being the supporting wafer is separated from the first device chips 15 or the second semiconductor wafer 20 bonded to the supporting board 40 with the adhesive agent 41 in the bonded wafer 50. As the supporting board 40 separates, as shown in FIG. 4, some or all of the adhesive agent 41 may remain on the supporting board 40. In order to manufacture a new bonded wafer 50 using the supporting board 40, it is desirable to remove the residual adhesive agent 41 from the supporting board 40.

In the method for reusing the supporting wafer according to the present embodiment, the adhesive agent 41 remaining on the separated supporting board 40 is removed by irradiating with a laser beam (adhesive agent removing process). In the adhesive agent removing process, the laser beam slightly defocused from the lower surface of the supporting board 40 is emitted, and the entire lower surface of the supporting board 40 is scanned with the laser beam in order to remove the adhesive agent 41. Specifically, as shown in FIG. 5, the supporting board 40 separated from the bonded wafer 50 is held against the holder table 60 and located above a laser unit 30 using the horizontal movable assembly 80 and the lift/lower assembly 90. Thereafter, while a laser beam L condensed by a condenser 31 of the laser unit 30 is focused on the residual adhesive agent 41 on the lower surface of the supporting board 40, a laser spot formed by the laser beam L is moved relatively to the supporting board 40 to scan the lower surface of the supporting board 40 with the laser beam L. As such, the adhesive agent 41 irradiated with the laser beam L is removed from the lower surface of the supporting board 40 so that the adhesive agent 41 is removed entirely from the lower surface of the supporting board 40.

In the apparatus that functions as a laser processing device, as shown in FIG. 5, it is preferable that the laser unit 30 emits short-wavelength laser pulses, which may be, for example, UV light of 266 nm or less. Using the UV light for photoablation allows the adhesive agent 41 to be removed while minimizing a heat-affected zone (HAZ). Therefore, the residual adhesive agent 41 may be removed from the lower surface accurately while minimizing damage to the supporting board 40.

For example, the laser processing device shown in FIG. 5 may operate preferably under the following laser processing conditions. A reference surface for a defocus amount is the lower surface of the supporting board 40.
Wavelength: 257.5 nm
Power Output: 0.5-1.5 W
Repetition Frequency: 100-200 kHz
Laser Overlap: 50% or more
Laser Spot Size: 20-60 μm
Defocus Amount: −2 mm
   In other words, a focal point of the laser beam L may be located 2 mm below the lower surface of the supporting board 40.

Optionally, for moving the laser beam L relatively in the laser processing apparatus, the horizontal movable assembly 80 may be operated to move the supporting board 40. Alternatively, a laser scanner (such as polygon mirror or galvanometer scanner), which is not shown but is located on a light path of the laser beam L, may deflect the laser beam L.

On the lower surface of the supporting board 40 scanned with the laser beam L, some of the adhesive agent 41 having been absorbed the energy of the laser beam L and chemically altered, more specifically, carbonized adhesive agent 41, may remain. Therefore, the adhesive agent removing process may include an additional process to remove the altered material from the lower surface of the supporting board 40 after irradiation with the laser beam L. Specifically, after irradiating with the laser beam L, it is preferable that a process such as two-fluid cleaning, CMP polishing, or wet etching may be performed.

The supporting board 40, from which the adhesive agent 41 has been removed in the adhesive agent removing process, is later reused for producing more provisional wafers and bonded wafers, allowing it to be repeatedly used in the manufacturing of laminated devices.

As described above, according to the method for reusing the supporting wafer in the present embodiment, the adhesive agent 41 remaining on the supporting board 40 may be removed by a laser beam without using an organic solvent. Therefore, a process to the waste liquid that may otherwise be required when using an organic solvent may be omitted, and the processing costs may be reduced while the supporting wafer may be recycled and reused.

Moreover, according to the method for reusing the supporting wafer in the present embodiment, by using the UV light, the adhesive agent 41 may be removed while minimizing the heat-affected zone (HAZ). Thereby, a removal area may be controlled accurately, and the adhesive agent 41 may be removed from the supporting board 40 reliably. Moreover, a negative impact on the supporting board 40 may be reduced, and the supporting board 40 may be reused over an extended period of time.

Embodiment of the present disclosure may not necessarily be limited to the configurations described above but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

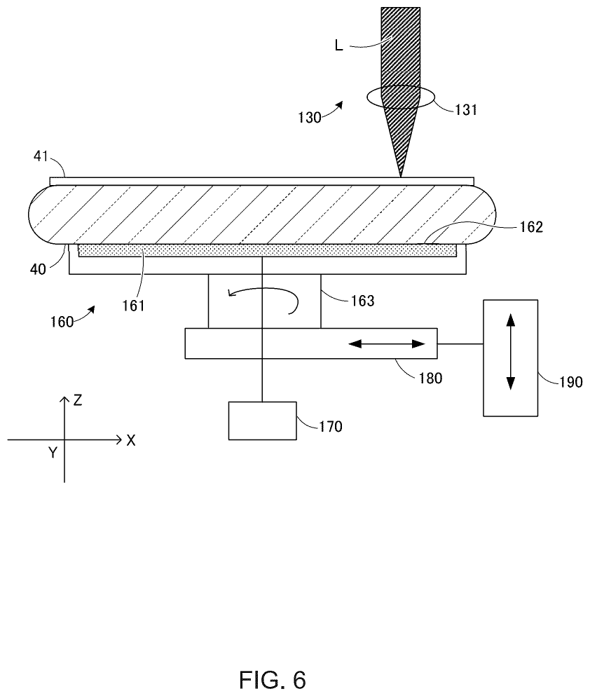

The above embodiment shows an example, in which the surface of the supporting board 40 having the adhesive agent 41 applied thereon faces downward, and the laser beam L is emitted upward at the supporting board 40 from the lower position to remove the adhesive agent 41. However, for example, as shown in FIG. 6, the laser processing apparatus may have a laser unit 130 above the supporting board 40 and have a holder table 160, a suction source 170, an X-axis movable assembly 180, and a Y-axis movable assembly 190 below the supporting board 40. For another example, in the laser processing apparatus shown in FIG. 6, the surface of the supporting board 40 having the adhesive agent 41 applied thereon may be arranged to face upward, and the laser beam L may be emitted downward at the supporting board 40 from the position above the supporting board 40 to remove the adhesive agent 41.

As explained above, according to the method for reusing the supporting wafer in the present disclosure, the adhesive agent may be removed from the supporting wafer without using an organic solvent to recycle the supporting wafer, and the recycled supporting wafer may be reused. As such, the method is advantageous in manufacturing laminated devices in which the supporting wafer is used.

What is claimed is:

1. A method for reusing a supporting wafer, the supporting wafer having chips or a wafer bonded thereon with an adhesive agent, by separating the supporting wafer from the chips or the wafer and thereafter removing the adhesive agent from the supporting wafer, the method comprising:
an adhesive agent removing process including irradiating the adhesive agent remaining on the supporting wafer after separating the supporting wafer from the chips or the wafer with a laser beam to remove the adhesive agent.

2. A method for manufacturing a plurality of chips, the chips being divided from a wafer on which a plurality of devices are formed respectively in a plurality of regions defined by a plurality of streets, the method comprising:
a bonding process including bonding the supporting wafer which is reused by application of the method for reusing the supporting wafer according to claim 1 to the wafer with the adhesive agent, and
a chip forming process including dividing the wafer along the streets to be divided into individual chips after the bonding process.
